(19) United States
(12) Patent Application Publication
(10) Pub. No.: US 2007/0008701 A1
(43) Pub. Date: Jan. 11, 2007

(54) Heat-dissipating device

(75) Inventors: Chin-Ming Cheng, Taoyuan Hsien (TW); Min-Hui Yu, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/263,830

(22) Filed: Nov. 2, 2005

(30) Foreign Application Priority Data
Jul. 6, 2005 (TW) 94211414

(51) Int. Cl. H05K 7/20

(52) U.S. Cl. 361/700; 361/704

(57) ABSTRACT

A heat-dissipating device. The heat-dissipating device includes a base, a plurality of heat-dissipating fins, and a fan. The heat-dissipating fins are disposed around the base. The base includes a first end surface and a second end surface. The first end surface contacts a heat source. The fan is disposed on the second end surface. An airflow space is formed between the heat-dissipating fins and the first end surface for airflow to pass through.

### BACKGROUND

The invention relates to a heat-dissipating device, and in particular, to a heat-dissipating device with reduced noise and improved cooling efficiency.

FIG. 1 depicts a known heat-dissipating device disposed on a circuit board 1042 to cool a central processing unit (CPU) 1041, wherein the heat-dissipating device 100 includes a heat sink 101, a base 102, and a fan 103. The heat sink 101 is located near the central processing unit (CPU) 1041 and the circuit board 1042, lowering the heat resistance therebetween. In other words, the space between the heat sink 101 and the circuit board 1042 is minimized, thereby lowering the heat resistance generated by the fan 103, increasing the airflow passing through the CPU and making an airless space 105 between the heat sink 101 and the circuit board 1042. As a result, electronic components in the vicinity of the central processing unit (CPU) 1041 cannot be effectively cooled. Thus, the performance of the electronic components is negatively influenced. Also, the fan 103 is noisy due to the raised airflow resistance.

### SUMMARY

To solve the described problems, the invention provides a heat-dissipating device with reduced noise and improved cooling efficiency.

A heat-dissipating device in accordance with an exemplary embodiment of the invention includes a base, a plurality of heat-dissipating fins, and a fan. The heat-dissipating fins are disposed around the base. The base includes a first end surface and a second end surface. The first end surface contacts a heat source. The fan is disposed on the second end surface. An airflow space is formed between the heat-dissipating fins and the first end surface and may be 5 mm-50 mm in height.

The heat source may be a central processing unit (CPU) or a circuit device.

### BRIEF DESCRIPTION OF THE DRAWINGS

The invention can be more fully understood by reading the subsequent detailed description and examples with references made to the accompanying drawings, wherein:

FIG. 1 is a schematic diagram of a heat-dissipating device of the prior art;

FIG. 2 is a schematic diagram of a heat-dissipating device in accordance with an embodiment of the invention;

FIG. 3 depicts the heat-dissipating device mounted on a heat source in accordance with the embodiment of the invention;

FIGS. 4A-1 and 4A-2 depict a heat-dissipating device of the prior art and a heat-dissipating device of the invention used in a test, respectively;

FIG. 4B shows the testing results measured in a wind tunnel; and

FIG. 5 shows the PQ curve obtained in the wind tunnel testing.

### DETAILED DESCRIPTION

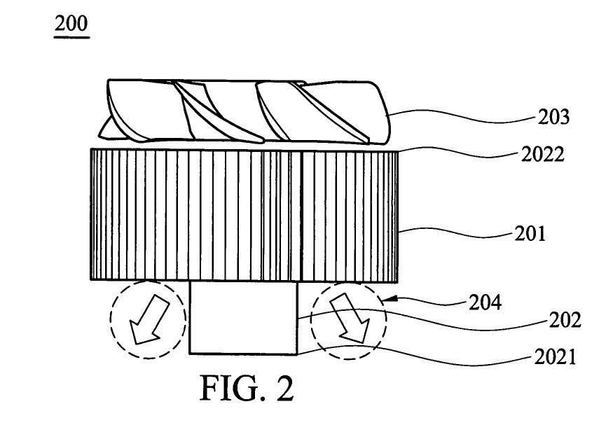

Referring to FIG. 2, a heat-dissipating device 200 in accordance with an embodiment of the invention includes a base 202, a plurality of heat-dissipating fins 201 and a fan 203. The heat-dissipating fins 201 are disposed around the base 202 and arranged in a circle. Specifically, the heat-dissipating fins 201 radiate from the base 202, facilitating airflow to pass therethrough. Each heat-dissipating fin 201 is planar in its entirety, or has a planar part and branches therefrom. Furthermore, the material of the heat-dissipating fins 201 is selected from the group consisting of aluminum, copper, aluminum alloy, copper alloy and a mixture thereof. The base 202 may be a hollow heat pipe (or a hollow copper pillar) with a working fluid flowing inside. The base 202 is made of an aluminum alloy or high-conductivity material.

The base 202 has a first end surface 2021 and a second end surface 2022. The first end surface 2021 contacts a heat source. The fan 203 is disposed on the second end surface 2022. An airflow space 204 is formed between the heat-dissipating fins 201 and the first end surface 2021 and may be 5 mm-50 mm in height.

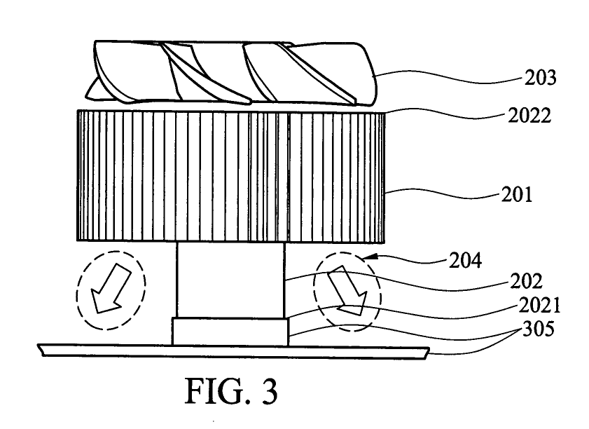

Referring to FIG. 3, the heat-dissipating device 200 of this embodiment may be used for dissipating heat from a heat source 305. The heat source 305 may be a central processing unit (CPU) or a circuit device. In operation, airflow passes through the airflow space 204 between the heat-dissipating fins 201 and the heat source 305, effectively dissipating heat from the heat source 305 and in the vicinity thereof. Compared to the prior art, the invention provides a heat-dissipating device having lower resistance generated by the fan and increasing the airflow passing through the heat source. Thus, the fan of the invention is capable of generating the same amount of airflow even though it operates at a lower rotational speed. Because the degree of noise generated by the fan is proportional to the rotational speed, the degree of noise produced by the invention is lower.

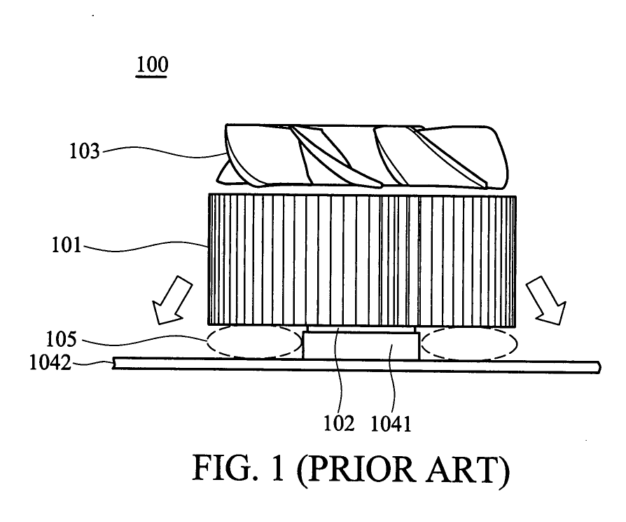

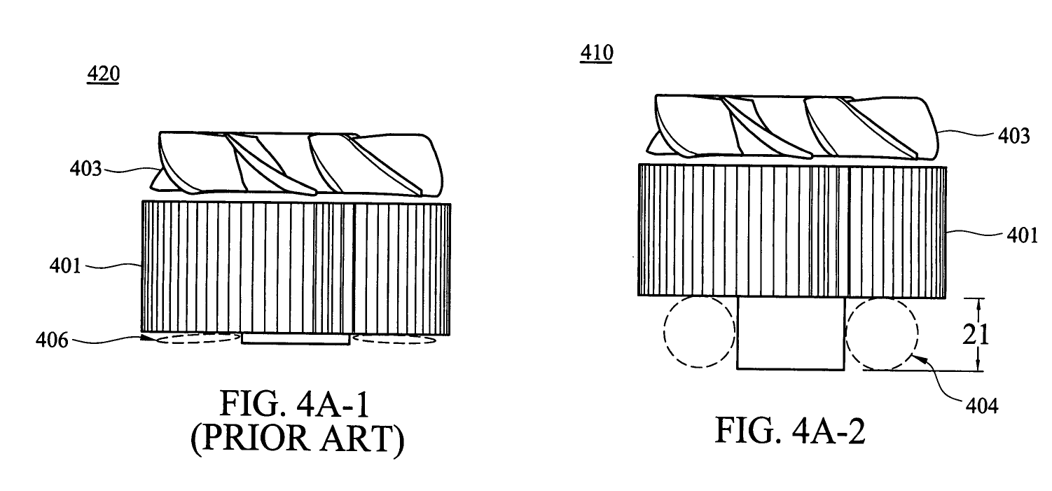

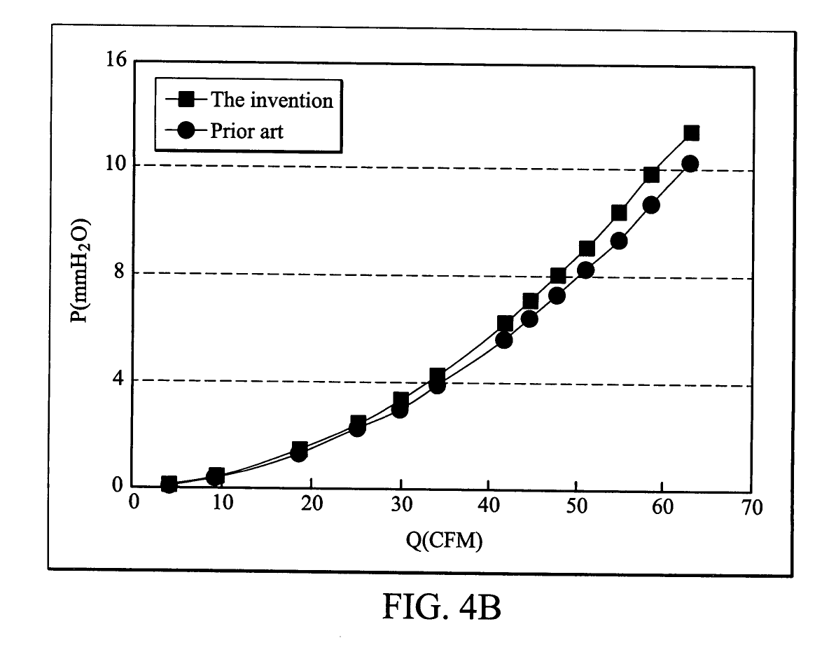

Referring to FIGS. 4A-1 and 4A-2, in a test, a heat-dissipating device 420 of the prior art and a heat-dissipating device 410 of the invention were provided with the same elements: a round fan 403 of 90 mm×90 mm×25 mm and a plurality of heat-dissipating fins 401. In the test, an airless space 406 was formed in the prior art, while an airflow space 404 was provided in the invention. The airflow space 404 was 21 mm in height. The results of the test are shown in FIG. 4B. For the same air pressure, the rotational speed of the fan of the invention was lower than that of the prior art.

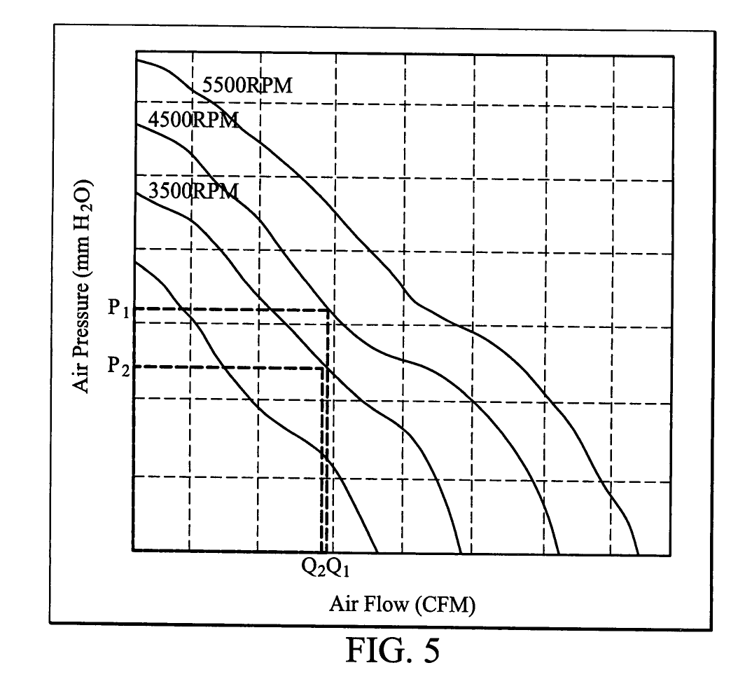

Referring to FIG. 5, for the heat-dissipating device of the prior art, the pressure and the volumn of airflow were respectively P₁ and Q₁ when the rotational speed of the fan was 4500 RPM. For the heat-dissipating device of the invention, the pressure and the volumn of airflow were respectively P₂ and Q₂, wherein P₂ was less than P₁. To provide the same volumn of airflow (i.e. Q₂=Q₁), the rotational speed of the fan of the invention was only 3500 RPM, which was less than the 4500 RPM of the prior art.

Compared to the prior art, the invention provides a heat-dissipating device capable of generating the same amount of airflow even though it operates at a lower rotational speed. Because the degree of noise generated by the fan is proportional to the rotational speed, the degree of noise produced by the invention is lower. Furthermore, the invention provides an airflow space between the heat-dissipating fins and the heat source for airflow to pass through, thereby cooling the heat source more efficiently and prolonging the life of the electronic components in the vicinity of the heat-dissipating device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat-dissipating device comprising:
a base comprising a first end surface contacting a heat source and a second end surface;
a plurality of heat-dissipating fins disposed around the base, with an airflow space formed between the plurality of heat-dissipating fins and the first end surface of the base; and
a fan disposed on the second end surface of the base.

2. The heat-dissipating device as claimed in claim 1, wherein the airflow space is 5 mm-50 mm in height.

3. The heat-dissipating device as claimed in claim 1, wherein the plurality of heat-dissipating fins are arranged in a circle.

4. The heat-dissipating device as claimed in claim 1, wherein the plurality of heat-dissipating fins radiate from the base.

5. The heat-dissipating device as claimed in claim 4, wherein each heat-dissipating fin is planar or has a planar part and branches therefrom.

6. The heat-dissipating device as claimed in claim 1, wherein the base is made of aluminum alloy or a high-conductivity material.

7. The heat-dissipating device as claimed in claim 1, wherein the base is a copper pillar.

8. The heat-dissipating device as claimed in claim 7, wherein the copper pillar is a hollow heat pipe with a working fluid inside.

9. The heat-dissipating device as claimed in claim 1, wherein the heat source is a central processing unit.

10. The heat-dissipating device as claimed in claim 1, wherein the material of the plurality of heat-dissipating fins is selected from the group consisting of aluminum, copper, aluminum alloy, copper alloy and a mixture thereof.
